(19) United States
(12) Patent Application Publication
(10) Pub. No.: US 2019/0134742 A1
(43) Pub. Date: May 9, 2019

(54) METHOD FOR LASER MARKING

(71) Applicant: POWERTECH TECHNOLOGY INC., HSINCHU COUNTY (TW)

(72) Inventors: Yun-Chieh Fang, HSINCHU COUNTY (TW); Sheng-Tou Tseng, HSINCHU COUNTY (TW); Cheng-Hung Song, HSINCHU COUNTY (TW); Sung-Hua Yang, HSINCHU COUNTY (TW)

(21) Appl. No.: 15/802,476

(22) Filed: Nov. 3, 2017

(51) Int. Cl. B23K 26/0622; B41M 5/26; B23K 26/00

(52) U.S. Cl. CPC B23K 26/0622; H01L 2223/54493; B23K 26/0006; B41M 5/262

(57) ABSTRACT

A method for laser marking includes steps of forming a test matter on a substrate; using a laser to form a laser path on the test matter; determining whether at least one of a first condition and a second condition occurs, wherein the first condition is a color of an abnormal area on the laser path is different from a color of the laser path and the second condition is a width of the abnormal area is larger than a width of the laser path; and when the at least one of the first condition and the second condition occurs, adjusting at least one laser parameter of the laser to prevent the at least one of the first condition and the second condition from occurring.

### BACKGROUND OF THE INVENTION

### 1. Field of the Invention

The invention relates to a method for laser marking and, more particularly, to a method for optimizing laser marking by a test matter formed on a substrate.

### 2. Description of the Prior Art

Product information (such as a company name, a serial number, or other information) is conventionally provided by means of a mark on a chip. For the chip manufactured using wafer level packaging technology, such marks are usually formed by laser marking. In general, the chip comprises a protection layer and the mark is formed on the protection layer by a laser, wherein the protection layer is used to insulate energy generated by the laser, so as to prevent the chip from being damaged by the laser. However, since the size of the chip is being miniaturized gradually, the protection layer is thinned correspondingly. Consequently, the energy generated by the laser may damage the chip during laser marking. In the prior art, the laser parameter are adjusted according to the depth and appearance of the mark formed on the protection layer only, so the prior art cannot ensure whether the laser will damage the chip no matter how the laser parameter is adjusted.

### SUMMARY OF THE INVENTION

The invention provides a method for optimizing laser marking by a test matter formed on a substrate, so as to solve the aforesaid problems.

According to an embodiment of the invention, a method for laser marking comprises steps of forming a test matter on a substrate; using a laser to form a laser path on the test matter; determining whether at least one of a first condition and a second condition occurs, wherein the first condition is a color of an abnormal area on the laser path is different from a color of the laser path and the second condition is a width of the abnormal area is larger than a width of the laser path; and when the at least one of the first condition and the second condition occurs, adjusting at least one laser parameter of the laser to prevent the at least one of the first condition and the second condition from occurring.

According to another embodiment of the invention, a method for laser marking comprises steps of forming a test matter on a substrate; forming a protection layer on the test matter; using a laser to form a laser mark on the protection layer; removing the protection layer from the test matter; determining whether there are different colors on the test matter; and determining that the protection layer is insufficient to insulate energy generated by the laser when there are different colors on the test matter.

As mentioned in the above, the invention uses the test matter to observe the energy generated by the laser during laser marking, so as to adjust the laser parameter according to the condition occurring on the test matter. Furthermore, in addition to adjusting the laser parameter, the invention may also use the test matter to determine whether the protection layer is sufficient to insulate the energy generated by the laser. When the protection layer is insufficient to insulate the energy generated by the laser, the invention may adjust the thickness, material, characteristic and so on of the protection layer, so as to enable the protection layer to insulate the energy generated by the laser completely. Accordingly, the invention can ensure that the laser will not damage the chip during laser marking after adjusting the laser parameter and/or the protection layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart illustrating a method for laser marking according to an embodiment of the invention.

FIG. 2 is a schematic view illustrating a test matter formed on a substrate.

FIG. 3 is a top view illustrating the test matter shown in FIG. 2 before adjusting the laser parameter of the laser.

FIG. 4 is a top view illustrating the test matter shown in FIG. 2 after adjusting the laser parameter of the laser.

FIG. 5 is a flowchart illustrating a method for laser marking according to another embodiment of the invention.

FIG. 6 is a schematic view illustrating a test matter formed on a substrate and a protection layer formed on the test matter.

FIG. 7 is a top view illustrating the protection layer shown in FIG. 6.

FIG. 8 is a top view illustrating the test matter shown in FIG. 6.

### DETAILED DESCRIPTION

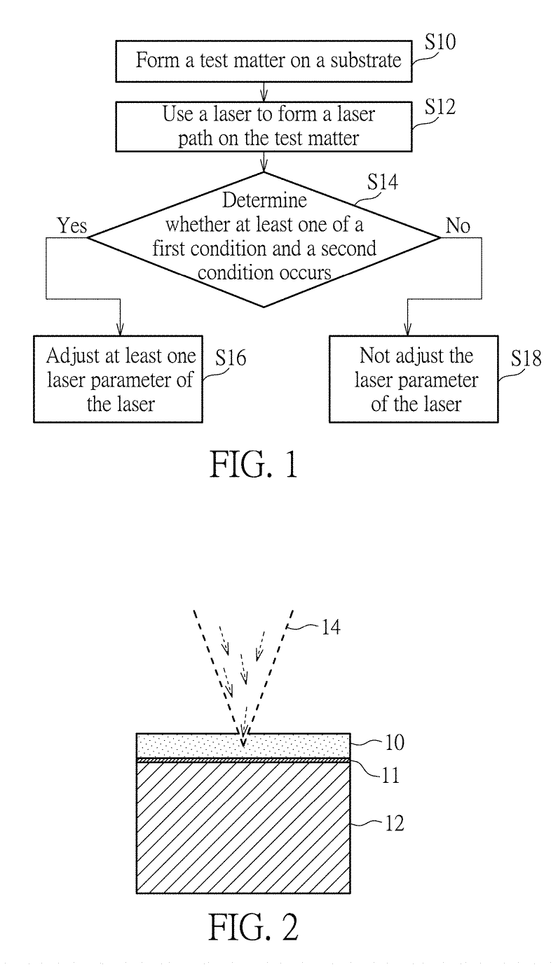

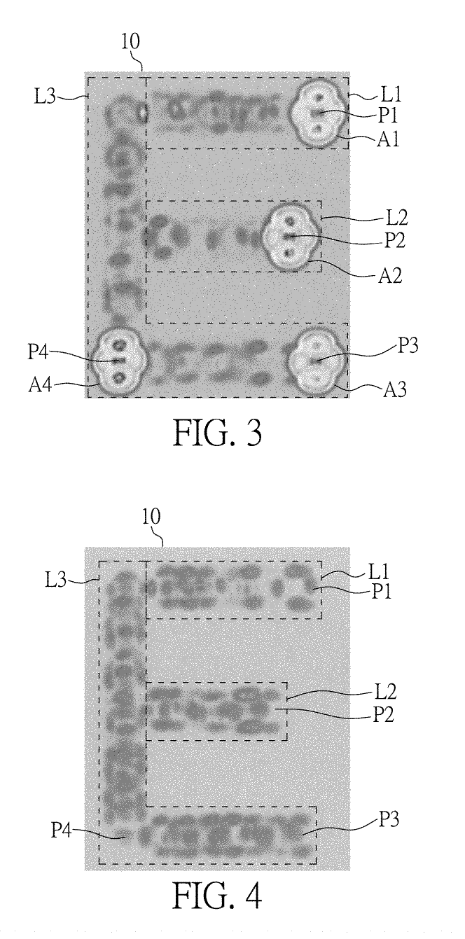

Referring to FIGS. 1 to 4, FIG. 1 is a flowchart illustrating a method for laser marking according to an embodiment of the invention, FIG. 2 is a schematic view illustrating a test matter 10 formed on a substrate 12, FIG. 3 is a top view illustrating the test matter 10 shown in FIG. 2 before adjusting the laser parameter of the laser 14, and FIG. 4 is a top view illustrating the test matter 10 shown in FIG. 2 after adjusting the laser parameter of the laser 14.

As shown in FIG. 2, the invention uses a test matter 10 to observe the energy generated by a laser 14 during laser marking, so as to adjust the laser parameter according to the condition occurring on the test matter 10. First, the method of the invention forms a test matter 10 on a substrate 12 (step S10 in FIG. 1). In this embodiment, the substrate 12 may be a wafer, a compound, etc. Furthermore, a melting point of the test matter 10 may be between 150° C. and 670° C. That is to say, the test matter 10 may be made of a material with the melting point between 150° C. and 670° C., such as, but not limited to, tin (Sn). It should be noted that a material may be served as the test matter 10 as long as the laser 14 can form a laser path on the material.

Moreover, if the test matter 10 cannot be formed on the substrate 12 directly due to material characteristics of the test matter 10 and the substrate 12, the method of the invention may form a medium layer 11 on the substrate 12 first and then form the test matter 10 on the medium layer 11. In other words, if the test matter 10 can be formed on the substrate 12 directly, the invention need not form the medium layer 11 on the substrate 12. In this embodiment, a material of the medium layer 11 may be, but not limited to, titanium (Ti).

Then, the method of the invention uses a laser 14 to form a laser path on the test matter 10 (step S12 in FIG. 1) to observe the energy generated by the laser 14 during laser marking. In this embodiment, the laser 14 may be Nd:YAG laser, Nd:YVO4 laser or other lasers. As shown in FIG. 3, the laser 14 may form three laser paths L1, L2, L3 on the test matter 10 to form a laser mark, wherein the laser paths L1, L2 are straight lines and the laser path L3 is L-shaped.

Then, the method of the invention determines whether at least one of a first condition and a second condition occurs (step S14 in FIG. 1), wherein the first condition is a color of an abnormal area on the laser path is different from a color of the laser path and the second condition is a width of the abnormal area is larger than a width of the laser path. As shown in FIG. 3, an abnormal area A1 is formed at a beginning position P1 of the laser path L1, an abnormal area A2 is formed at a beginning position P2 of the laser path L2, an abnormal area A3 is formed at a beginning position P3 of the laser path L3, and an abnormal area A4 is formed at a corner position P4 of the laser path L3.

When the at least one of the first condition and the second condition occurs, it means that the energy generated by the laser 14 may damage the chip during laser marking. Accordingly, the laser parameter of the laser 14 needs to be adjusted to prevent the chip from being damaged by the laser 14. Therefore, when the at least one of the first condition and the second condition occurs, the method of the invention adjusts at least one laser parameter of the laser 14 to prevent the at least one of the first condition and the second condition from occurring (step S16 in FIG. 1).

On the other hand, when the at least one of the first condition and the second condition does not occur, it means that the energy generated by the laser 14 will not damage the chip during laser marking. Accordingly, the laser parameter of the laser 14 need not be adjusted. Therefore, when the at least one of the first condition and the second condition does not occur, the method of the invention does not adjust the laser parameter of the laser 14 (step S18 in FIG. 1).

As shown in FIG. 3, since the colors of the abnormal areas A1, A2, A3, A4 are different from the colors of the laser paths L1, L2, L3, the method of the invention determines the first condition occurs in step S14. In this embodiment, the colors of the abnormal areas A1, A2, A3, A4 may be deeper or lighter than the colors of the laser paths L1, L2, L3 according to practical applications. Furthermore, since the widths of the abnormal areas A1, A2, A3, A4 are larger than the widths of the laser paths L1, L2, L3, the method of the invention determines the second condition occurs in step S14. In this embodiment, the invention may determine that the second condition occurs when the widths of the abnormal areas A1, A2, A3, A4 are larger than one and a half times the widths of the laser paths L1, L2, L3.

In this embodiment, the at least one laser parameter may comprise a first pulse suppression of the laser 14, a power of the laser 14, a frequency of the laser 14, and a duration of the laser 14 staying at the corner position of the laser path. When the abnormal area is formed at the beginning position of the laser path, the invention may adjust the first pulse suppression of the laser 14, the power of the laser 14, and the frequency of the laser 14 to prevent the at least one of the first condition and the second condition from occurring. When the abnormal area is formed at the corner position of the laser path, the invention may adjust the duration of the laser 14 staying at the corner position of the laser path to prevent the at least one of the first condition and the second condition from occurring.

When the at least one of the first condition and the second condition occurs at the beginning position of the laser path, the method of the invention may increase the first pulse suppression of the laser 14, decrease the power of the laser 14, and/or increase the frequency of the laser 14 to prevent the at least one of the first condition and the second condition from occurring.

As shown in FIG. 3, the abnormal areas A1, A2, A3 are formed at the beginning positions P1, P2, P3 of the laser paths L1, L2, L3, i.e. the at least one of the first condition and the second condition occurs at the beginning positions P1, P2, P3 of the laser paths L1, L2, L3. Accordingly, the method of the invention may increase the first pulse suppression of the laser 14 first and then use the laser 14 to form another laser path on the test matter 10 to determine whether the at least one of the first condition and the second condition still occurs at the beginning position of the laser path. Once the at least one of the first condition and the second condition still occurs at the beginning position of the laser path, the method of the invention may increase the first pulse suppression of the laser 14 again and then use the laser 14 to form another laser path on the test matter 10. When the at least one of the first condition and the second condition does not occur at the beginning position of the laser path (as shown in FIG. 4) after adjusting the first pulse suppression of the laser 14, the laser 14 can be used to form a laser mark on a chip and the chip will not be damaged by the laser 14 during laser marking. It should be noted that the value of increasing the first pulse suppression of the laser 14 every time may be determined according to practical applications.

When the at least one of the first condition and the second condition still occurs at the beginning position of the laser path after adjusting the first pulse suppression of the laser 14 for a predetermined times (e.g. 10, 15, etc.), the method of the invention may further decrease the power of the laser 14 and then use the laser 14 to form another laser path on the test matter 10 to determine whether the at least one of the first condition and the second condition still occurs at the beginning position of the laser path. It should be noted that the aforesaid predetermined times may be determined according to practical applications. Once the at least one of the first condition and the second condition still occurs at the beginning position of the laser path, the method of the invention may decrease the power of the laser 14 again and then use the laser 14 to form another laser path on the test matter 10. When the at least one of the first condition and the second condition does not occur at the beginning position of the laser path (as shown in FIG. 4) after adjusting the power of the laser 14, the laser 14 can be used to form a laser mark on a chip and the chip will not be damaged by the laser 14 during laser marking. It should be noted that the value of decreasing the power of the laser 14 every time may be determined according to practical applications.

When the at least one of the first condition and the second condition still occurs at the beginning position of the laser path after adjusting the power of the laser 14 for a predetermined times, the method of the invention may further increase the frequency of the laser 14 and then use the laser 14 to form another laser path on the test matter 10 to determine whether the at least one of the first condition and the second condition still occurs at the beginning position of the laser path. It should be noted that the aforesaid predetermined times may be determined according to practical applications. Once the at least one of the first condition and the second condition still occurs at the beginning position of the laser path, the method of the invention may increase the frequency of the laser 14 again and then use the laser 14 to form another laser path on the test matter 10. When the at least one of the first condition and the second condition does not occur at the beginning position of the laser path (as shown in FIG. 4) after adjusting the frequency of the laser 14, the laser 14 can be used to form a laser mark on a chip and the chip will not be damaged by the laser 14 during laser marking. It should be noted that the value of increasing the frequency of the laser 14 every time may be determined according to practical applications.

When the at least one of the first condition and the second condition occurs at the corner position of the laser path, the method of the invention may decrease the duration of the laser 14 staying at the corner position of the laser path to prevent the at least one of the first condition and the second condition from occurring.

As shown in FIG. 3, the abnormal area A4 is formed at the corner position P4 of the laser path L3, i.e. the at least one of the first condition and the second condition occurs at the corner position P4 of the laser path L3. Accordingly, the method of the invention may decrease the duration of the laser 14 staying at the corner position P4 of the laser path L3 and then use the laser 14 to form another laser path on the test matter 10 to determine whether the at least one of the first condition and the second condition still occurs at the corner position of the laser path. Once the at least one of the first condition and the second condition still occurs at the corner position of the laser path, the method of the invention may decrease the duration of the laser 14 staying at the corner position of the laser path again and then use the laser 14 to form another laser path on the test matter 10. When the at least one of the first condition and the second condition does not occur at the corner position of the laser path (as shown in FIG. 4) after adjusting the duration of the laser 14 staying at the corner position of the laser path, the laser 14 can be used to form a laser mark on a chip and the chip will not be damaged by the laser 14 during laser marking. It should be noted that the value of decreasing the duration of the laser 14 staying at the corner position of the laser path every time may be determined according to practical applications.

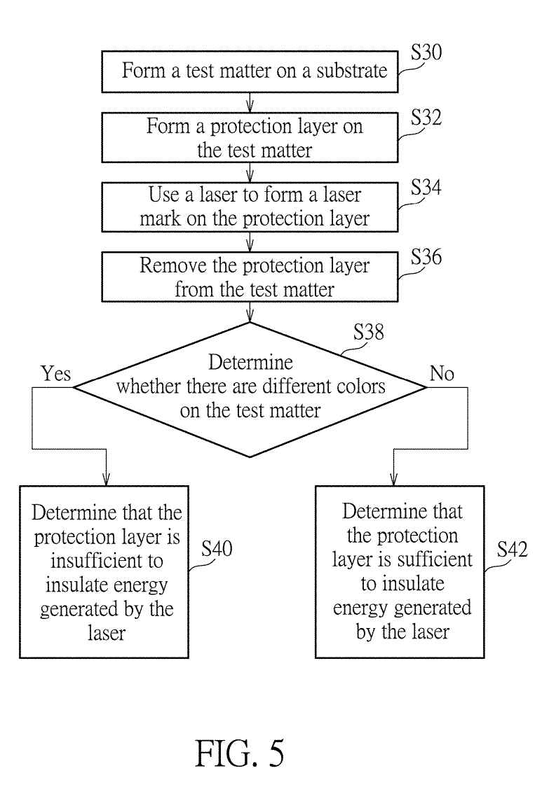

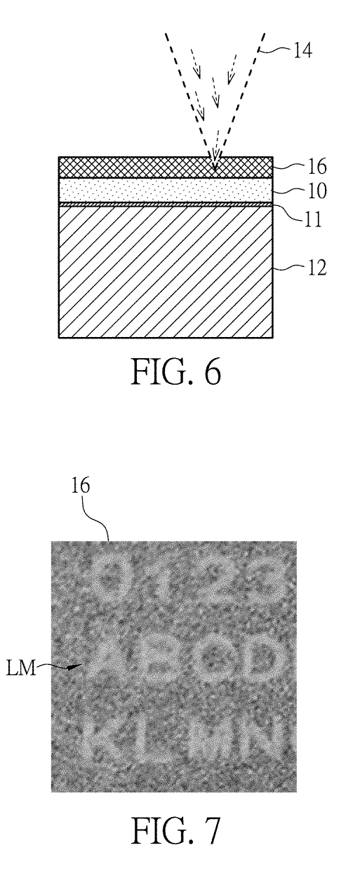

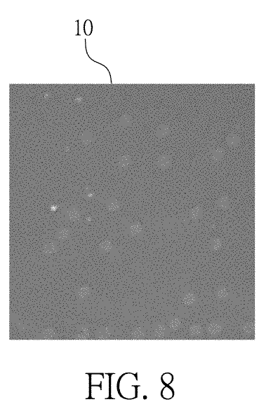

Referring to FIGS. 5 to 8, FIG. 5 is a flowchart illustrating a method for laser marking according to another embodiment of the invention, FIG. 6 is a schematic view illustrating a test matter 10 formed on a substrate 12 and a protection layer 16 formed on the test matter 10, FIG. 7 is a top view illustrating the protection layer 16 shown in FIG. 6, and FIG. 8 is a top view illustrating the test matter 10 shown in FIG. 6.

As shown in FIG. 6, the invention uses a test matter 10 to observe the energy generated by a laser 14 during laser marking to determine whether the protection layer 16 is sufficient to insulate the energy generated by the laser 14. First, the method of the invention forms a test matter 10 on a substrate 12 (step S30 in FIG. 5). In this embodiment, the substrate 12 may be a wafer, a compound, etc. Furthermore, a melting point of the test matter 10 may be between 150° C. and 670° C. That is to say, the test matter 10 may be made of a material with the melting point between 150° C. and 670° C., such as, but not limited to, tin (Sn). It should be noted that a material may be served as the test matter 10 as long as the laser 14 can form a laser path on the material.

Moreover, if the test matter 10 cannot be formed on the substrate 12 directly due to material characteristics of the test matter 10 and the substrate 12, the method of the invention may form a medium layer 11 on the substrate 12 first and then form the test matter 10 on the medium layer 11. In other words, if the test matter 10 can be formed on the substrate 12 directly, the invention need not form the medium layer 11 on the substrate 12. In this embodiment, a material of the medium layer 11 may be, but not limited to, titanium (Ti).

Then, the method of the invention forms a protection layer 16 on the test matter 10 (step S32 in FIG. 5). In this embodiment, a material of the protection layer 16 may be molding compound, rubber or the like.

Then, the method of the invention uses a laser 14 to form a laser mark LM on the protection layer 16 (step S34 in FIG. 5) to observe the energy generated by the laser 14 during laser marking. In this embodiment, the laser 14 may be Nd:YAG laser, Nd:YVO4 laser or other lasers. As shown in FIG. 7, the laser mark LM may consist of a plurality of numerals and letters. However, the content of the laser mark LM may be determined according to practical applications and the invention is not limited to the embodiment shown in FIG. 7.

Then, the method of the invention removes the protection layer 16 from the test matter 10 (step S36 in FIG. 5) and then determine whether there are different colors on the test matter 10 (step S38 in FIG. 5).

When there are different colors on the test matter 10 (as shown in FIG. 8), it means that the energy generated by the laser 14 may pass through the protection layer 16 and damage the chip during laser marking. Accordingly, the method of the invention determines that the protection layer 16 is insufficient to insulate energy generated by the laser 14 when there are different colors on the test matter 10 (step S40 in FIG. 5). When the protection layer 16 is insufficient to insulate the energy generated by the laser 14, the invention may adjust the thickness, material, characteristic and so on of the protection layer 16, so as to enable the protection layer 16 to insulate the energy generated by the laser 14 completely.

On the other hand, when the color of the test matter 10 is uniform, it means that the protection layer 16 can insulate the energy generated by the laser 14 completely and the energy generated by the laser 14 will not damage the chip during laser marking. Accordingly, the protection layer 16 needs not to be adjusted. Therefore, when the color of the test matter 10 is uniform, the method of the invention determines that the protection layer 16 is sufficient to insulate energy generated by the laser 14 (step S42 in FIG. 5).

As mentioned in the above, the invention uses the test matter to observe the energy generated by the laser during laser marking, so as to adjust the laser parameter according to the condition occurring on the test matter. Furthermore, in addition to adjusting the laser parameter, the invention may also use the test matter to determine whether the protection layer is sufficient to insulate the energy generated by the laser. When the protection layer is insufficient to insulate the energy generated by the laser, the invention may adjust the thickness, material, characteristic and so on of the protection layer, so as to enable the protection layer to insulate the energy generated by the laser completely. Accordingly, the invention can ensure that the laser will not damage the chip during laser marking after adjusting the laser parameter and/or the protection layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for laser marking comprising steps of:
forming a test matter on a substrate;
using a laser to form a laser path on the test matter;
determining whether at least one of a first condition and a second condition occurs, wherein the first condition is a color of an abnormal area on the laser path is different from a color of the laser path and the second condition is a width of the abnormal area is larger than a width of the laser path; and
when the at least one of the first condition and the second condition occurs, adjusting at least one laser parameter of the laser to prevent the at least one of the first condition and the second condition from occurring.

2. The method of claim 1, wherein the abnormal area is formed at a beginning position of the laser path, the at least one laser parameter comprises a first pulse suppression of the laser, and the method further comprises step of:
when the at least one of the first condition and the second condition occurs at the beginning position, increasing the first pulse suppression of the laser.

3. The method of claim 2, wherein the at least one laser parameter further comprises a power of the laser and the method further comprises step of:
when the at least one of the first condition and the second condition still occurs at the beginning position after adjusting the first pulse suppression of the laser for a predetermined times, decreasing the power of the laser.

4. The method of claim 3, wherein the at least one laser parameter further comprises a frequency of the laser and the method further comprises step of:
when the at least one of the first condition and the second condition still occurs at the beginning position after adjusting the power of the laser for a predetermined times, increasing the frequency of the laser.

5. The method of claim 1, wherein the abnormal area is formed at a corner position of the laser path, the at least one laser parameter comprises a duration of the laser staying at the corner position, and the method further comprises step of:
when the at least one of the first condition and the second condition occurs at the corner position, decreasing the duration of the laser staying at the corner position.

6. The method of claim 1, further comprising step of:
determining that the second condition occurs when the width of the abnormal area is larger than one and a half times the width of the laser path.

7. The method of claim 1, wherein a melting point of the test matter is between 150° C. and 670° C.

8. The method of claim 1, wherein the step of forming a test matter on a substrate further comprises steps of:
forming a medium layer on the substrate; and
forming the test matter on the medium layer.

9. The method of claim 1, further comprising steps of:
forming a protection layer on the test matter;
using the laser to forma laser mark on the protection layer;
removing the protection layer from the test matter;
determining whether there are different colors on the test matter; and
determining that the protection layer is insufficient to insulate energy generated by the laser when there are different colors on the test matter.

10. The method of claim 9, wherein a material of the protection layer is molding compound or rubber.

11. A method for laser marking comprising steps of:
forming a test matter on a substrate;
forming a protection layer on the test matter;
using a laser to form a laser mark on the protection layer;
removing the protection layer from the test matter;
determining whether there are different colors on the test matter; and
determining that the protection layer is insufficient to insulate energy generated by the laser when there are different colors on the test matter.

12. The method of claim 11, wherein a melting point of the test matter is between 150° C. and 670° C.

13. The method of claim 11, wherein the step of forming a test matter on a substrate further comprises steps of:
forming a medium layer on the substrate; and
forming the test matter on the medium layer.

14. The method of claim 11, wherein a material of the protection layer is molding compound or rubber.
